(19) United States
(12) Patent Application Publication
(10) Pub. No.: US 2010/0252856 A1
(43) Pub. Date: Oct. 7, 2010

(54) Header structure of opto-electronic element and opto-electronic element using the same

(75) Inventor: Rong-Heng Yuang, Hsinchu (TW)

Correspondence Address: CHARLES E. BAXLEY, ESQUIRE, 90 JOHN STREET, SUITE 309, NEW YORK, NY, 10038, US

(73) Assignee: Coretek Opto Corp.

(21) Appl. No.: 12/802,557

(22) Filed: Jun. 9, 2010

Related U.S. Application Data
(63) Continuation-in-part of application No. 12/322,085, filed on Jan. 28, 2009.
(60) Provisional application No. 61/268,247, filed on Jun. 10, 2009.

(51) Int. Cl. H01L 33/62; H01L 31/02; G02B 6/36

(52) U.S. Cl. 257/99; 257/459; 385/92; 257/E33.066; 257/E31.11

(57) ABSTRACT

An opto-electronic element includes a header and an opto-electronic chip. The header have a metal stem and an insulating structure, and the opto-electronic chip located on the stem or insulating structure. The opto-electronic chip is grown with an epitaxy layer structure on a thicker and homogeneous electroconductive base, and the electrodes are located on the same side and have the same metal structure. Thus, the chip is located on the insulating structure and isolated from each electrode, and the chip and header are kept in an insulated state. Furthermore, an auxiliary pin for supporting the chip and for forming an open circuit or serving as an electrode of the chip is located in an axial direction of the insulating structure. The combination of the stem and insulating structure may be replaced with a non-metal stem with a corresponding shape, and a periphery of the non-metal stem may further have an extended wall portion combined with a cap to form the opto-electronic element.

This application is a Continuation-in-Part of co-pending application Ser. No. 12/322,085, filed on Jan. 28, 2009, and claims priority of U.S. Provisional Patent Application No. 61/268,247 filed Jun. 10, 2009 under 35 USC 119, the entire contents of which are hereby incorporated by reference.

### BACKGROUND OF THE INVENTION

1. Field of the Invention

The invention relates to the field of the opto-electronic technology, and more particularly to an element used in an opto-electronic communication and a header of the element.

2. Related Art

A header of an opto-electronic element includes a combination of a metal stem and metal pins, such as To-can Header, and a combination of a non-metal stem and the metal pins, such as Leadframe Header. A submount for supporting an opto-electronic chip may be located on each header, and electrodes of the opto-electronic chip are connected to a circuit on a circuit board via pins.

The electrodes of the opto-electronic chip may be located on opposite sides. For example, one of the electrodes is located on a top surface of the opto-electronic chip, and the other one of the electrodes is located on a bottom surface of the opto-electronic chip. When the opto-electronic chip is located on the submount, the electrode on the bottom surface may be in contact with the submount to form the electrical connection. The submount further serves as a bonding pad so that a wire may connect a pin (an electrode) to the submount. The electrode located on the top surface of the opto-electronic chip may also be electrically connected to another pin (electrode) via a wire. It is to be noted that the surfaces of the submount and the header need to be in a non-electroconductive state.

FIGS. 1a and 1b show that two electrodes of the opto-electronic chip are located on the different side. Taking an opto-electronic element with the PIN-TIA architecture as an example, an opto-electronic chip 200 is located on a heterogeneous substrate/submount 205, which is located on a header 201. The opto-electronic chip 200 is electrically connected to a transimpedance amplifier (TIA) 202, and the opto-electronic chip 200 is insulated from the header 201 and may be operated. However, the heterogeneous substrate 205 has the higher price, the larger size and the larger area. So, the capacitance of the opto-electronic chip 200 is increased and the frequency response is lowered.

FIGS. 1c and 1d show another example, in which the opto-electronic chip 200 can be insulatively located on the header 201 and can be operated. A P-I-N structure is formed on a homogeneous semi-insulating substrate (SI substrate) 206 by way of epitaxy, and two electrodes 203 and 204 are formed by way of etching. However, the homogeneous SI substrate 206 still has the drawback of the high cost, and the N+ layer is very thin (the thickness is usually equal to only several microns (um)). So, the precise etching process has to be adopted to prevent the N+ epitaxy layer from being etched through to damage the element.

In addition, U.S. Pat. No. 6,586,718 discloses an opto-electronic chip, in which a P-I-N layer is formed on a homogeneous semi-insulating substrate by way of epitaxy, wherein the N epitaxy layer tends to be etched through due to over etching.

As mentioned hereinabove, the use of the heterogeneous substrate increases the cost and decreases the bandwidth in order to form the insulation between the opto-electronic chip and the header in the opto-electronic element with the conventional PIN-TIA architecture. In addition to the increase of the cost, the use of the homogeneous semi-insulating substrate increases the difficulty of manufacturing because the N+ epitaxy layer is thin and the etching process cannot be easily controlled so that the processing parameters should be very precise.

### SUMMARY OF THE INVENTION

One of the objectives of the invention is to provide a header of an opto-electronic element. The header has an insulating structure or an insulating region, and when an opto-electronic chip is mounted on the insulating structure, the opto-electronic chip is electrically insulated from the header.

Another object of the invention is to provide a header of an opto-electronic element having an insulating structure, wherein an auxiliary pin is combined with the insulating structure and supports an opto-electronic chip. Adjusting the length of the auxiliary pin can adjust the height of the opto-electronic chip. In addition, when the opto-electronic element is positioned on a circuit board, the auxiliary pin can serve as an electrode for connecting circuit board if the length is enough, or separate off the circuit board if the length is not enough.

Still another object of the invention is to provide a header of an opto-electronic element having a ring-shaped extended wall portion located on a periphery of a stem of the header, wherein the extended wall portion and a cap are combined together to form the opto-electronic element so that the effect of easy assembling can be achieved.

The invention also discloses an opto-electronic element having an opto-electronic chip located on an insulating structure of a header. More particularly, a thicker and electroconductive homogeneous base (N+ base) is for being located on one end of the opto-electronic chip, and two electrodes are located on the same side and preferably have the same metal layers. The low-K material (e.g., BCB or SOG) may be adopted to decrease the capacitance, or the SOG is formed on the bottom to form the insulation from the base. Thus, the opto-electronic element could reach higher bandwidth, lower cost, and higher yield or could be easier manufactured.

The foregoing and other features, aspects and advantages of the present invention will become better understood from a careful reading of a detailed description provided herein below with appropriate reference to the accompanying drawings and reference incorporated.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1a is a schematic illustration showing a conventional PIN-TIA structure.

FIG. 1b is another schematic illustration showing the conventional PIN-TIA structure.

FIG. 1c is a schematic illustration showing another conventional PIN-TIA structure.

FIG. 1d is another schematic illustration showing the another conventional PIN-TIA structure.

FIG. 2 is a schematic plane view showing a first embodiment of the invention.

FIG. 3 is a schematically cross-sectional view showing the first embodiment of the invention.

FIG. 4a is a schematic illustration showing an insulating structure having one projecting end according to the first embodiment of the invention combined with a cap.

FIG. 4b is a schematic illustration showing an insulating structure having one depressed end according to the first embodiment of the invention combined with a cap.

FIG. 5 is a schematic plane view showing a second embodiment of the invention.

FIG. 6 is a schematically cross-sectional view showing the second embodiment of the invention.

FIG. 7a is a schematic illustration showing an insulating structure having one projecting end according to the second embodiment of the invention combined with a cap.

FIG. 7b is a schematic illustration showing an insulating structure having one depressed end according to the second embodiment of the invention combined with a cap.

FIG. 8a is a schematic illustration showing a structure having an auxiliary pin according to a third embodiment of the invention.

FIG. 8b is a schematic illustration showing the structure of the auxiliary pin having one projecting end, which supports the opto-electronic chip and is in an open state according to the third embodiment of the invention.

FIG. 8c is a schematic illustration showing the structure of the auxiliary pin having one projecting end, which supports the opto-electronic chip and is in a state serving as an electrode.

FIG. 9a is a schematic plane view showing a fourth embodiment of the invention.

FIG. 9b is a schematically cross-sectional view showing the fourth embodiment of the invention.

FIG. 9c is a schematic plane view showing a fifth embodiment of the invention.

FIG. 9d is a schematically cross-sectional view showing the fifth embodiment of the invention.

FIG. 9e is a schematically cross-sectional view showing a pedestal formed on the insulating structure according to the fifth embodiment of the invention.

FIG. 9f is a schematic illustration showing a structure, in which an auxiliary pin is located in an axial direction of the insulating structure, according to the fifth embodiment of the invention combined with a cap.

FIG. 10a is a structure schematic illustration showing a sixth embodiment of the invention combined with a cap.

FIG. 10b is a schematic illustration showing a structure according to the sixth embodiment of the invention combined with a cap, wherein an auxiliary pin is located in the axial direction of the insulating structure to support the opto-electronic chip.

FIG. 10c is a schematic illustration showing a structure, which further has a supporting structure combined with an optical device, according to the sixth embodiment of the invention.

FIG. 11a is a schematic illustration showing a structure according to a seventh embodiment of the invention.

FIG. 11b is a schematic illustration showing a structure according to the seventh embodiment of the invention, wherein the opto-electronic chip is located within a range of an opening of the metal film and located, on the surface of the non-metal stem.

FIG. 11c is a schematic illustration showing the structure according to the seventh embodiment of the invention, wherein the opto-electronic chip is located on an end portion of the pedestal of the non-metal stem.

FIG. 12a is a schematic illustration showing the structure according to the seventh embodiment of the invention, wherein the header has an extended wall portion and is combined with a cap.

FIG. 12b is a schematic illustration showing the structure according to the seventh embodiment of the invention, wherein the header has an extended wall portion, is combined with a cap, and has an auxiliary pin.

FIG. 13a is a structure schematic illustration showing an eighth embodiment of the invention combined with a cap.

FIG. 13b shows the exterior according to a ninth embodiment of the invention.

FIG. 13c is a schematic illustration showing a continuous sheet-like structure formed by combining the header of the invention with each electrode pin.

FIG. 13d is another schematic illustration showing a continuous sheet-like structure formed by combining the header of the invention with each electrode pin.

FIGS. 13e to 13k are schematic illustrations each showing each electrode pin of the invention combined with the header in a horizontal direction.

FIGS. 14a to 14e show first to fifth implemented structures of the insulating structure of the invention.

FIGS. 15a to 15k show first to ninth structures of the opto-electronic chip of the invention.

FIG. 16a is a schematic illustration showing a first structure of the opto-electronic chip of the invention combined with the header.

FIG. 16b is a schematic illustration showing the first structure of the opto-electronic chip of the invention combined with the header and the transimpedance amplifier.

FIG. 17 is a schematic illustration showing a second structure of the opto-electronic chip of the invention combined with the header.

### DETAILED DESCRIPTION OF THE INVENTION

The present invention will be apparent from the following detailed description, which proceeds with reference to the accompanying drawings, wherein the same references relate to the same elements.

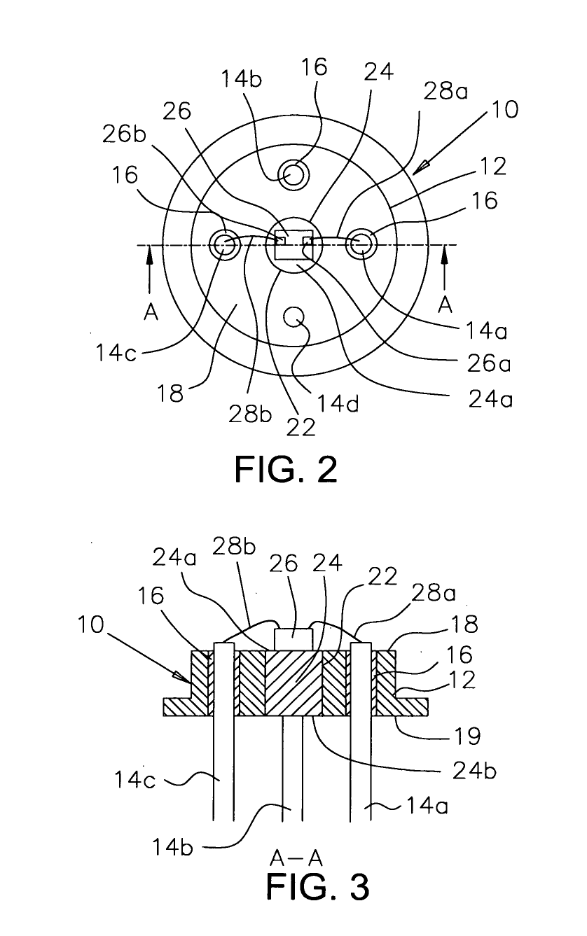

FIGS. 2 and 3 show the structure of a header 10 of an opto-electronic element. The header 10 has a metal stem 12, a plurality of pin-leads 14a to 14c that may serve as electrodes, and a ground electrode 14d. One end of each of the electrodes 14a to 14d may be inserted into the metal stem 12. More particularly, the pin-leads 14a to 14c may be used in conjunction to a non-electroconductive material 16, such as glass, plastic material or any other similar material, so that the metal stem 12 is electrically insulated from each of the pin-leads 14a to 14c.

Furthermore, the metal stem 12 has a first surface (stem surface) 18, and a second surface (bottom surface) 19 opposite the first surface 18. The first and second surfaces may be the upper and bottom surfaces shown in the drawing. An insert hole 22 is formed between the first surface 18 and the second surface 19 and located in a central region of the first surface 18. An insulating structure 24, which is an insert element made of an insulating material, is assembled into the insert hole 22 or is formed in the insert hole 22 by way of insert molding. The insulating structure 24 may be entirely or partially located between the first surface 18 and the second surface 19 of the stem 12, and the insulating structure 24 is for supporting an opto-electronic chip 26.

More particularly, the insulating structure 24 has a first end 24a and a second end 24b, wherein the first end 24a may neighbor and may be level with the first surface 18, and the first end 24a supports the opto-electronic chip 26. The insulating structure 24 may be an independent insulating element or an insulating part.

The opto-electronic chip 26 having electrodes 26a and 26b located on the same side is selected, and the opto-electronic chip 26 is located on the first end 24a of the insulating structure 24. In this case, wires 28a and 28b may connect the electrodes 26a and 26b to the electrodes 14a and 14c, respectively. In this state, the opto-electronic chip 26 and the metal stem 12 of the header 10 become the non-electroconductive open state.

The above-mentioned embodiment provides a novel structure of the header 10, which can be electrically insulated from the opto-electronic chip 26, and is different from the conventional header, in which the submount has to be adopted to support the opto-electronic chip or the insulating layer has to be formed on the opto-electronic chip.

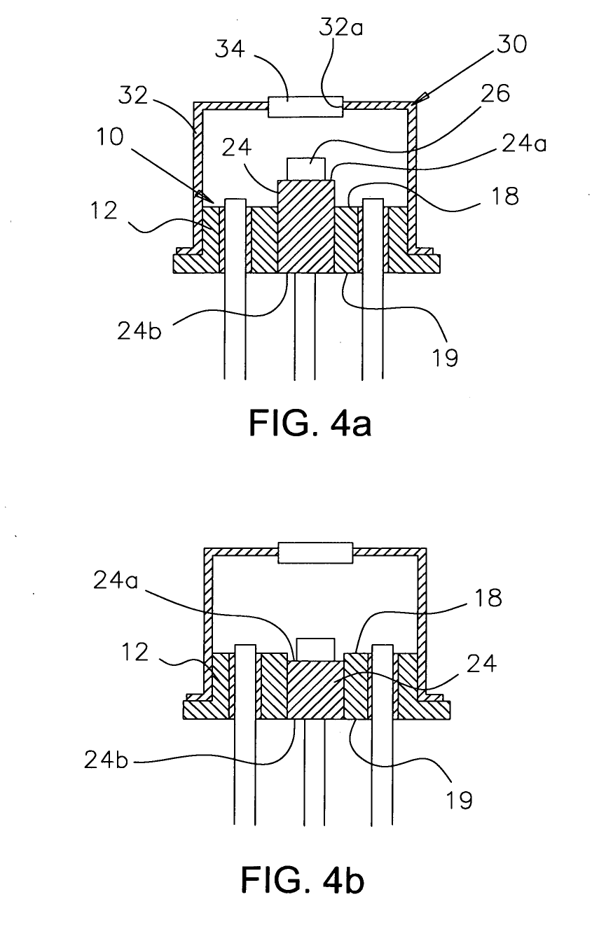

FIG. 4a shows that an opto-electronic element 30 may include the header 10 and the opto-electronic chip 26, and may further include a cap 32 located on the header 10. One end of the cap 32 has an opening 32a, and an optical device 34, such as a lens or a glass piece, may be located in the opening 32a. Alternatively, no element or device is located in the opening 32a. The opening 32a or optical device 34 is located opposite the opto-electronic chip 26.

Also, FIG. 4a shows that the first end 24a of the insulating structure 24 projects beyond the first surface 18 of the metal stem 12. Thus, the opto-electronic chip 26 located on the first end 24a of the insulating structure 24 can be electrically insulated from the metal stem 12, and the distance between the device 34 or the opening 32a of the chip 26 may be changed by changing the projecting height of the first end 24a, so that the light coupling efficiency can be adjusted.

According to the teachings of the above-mentioned embodiment, FIG. 4b shows that the first end 24a of the insulating structure 24 may be lower than the first surface 18 of the metal stem 12.

In FIG. 4a or 4b, the second end 24b of the insulating structure 24 may be higher than, level with or lower than the second surface 19 of the metal stem 12, or the following descriptions of the embodiments may be referred to.

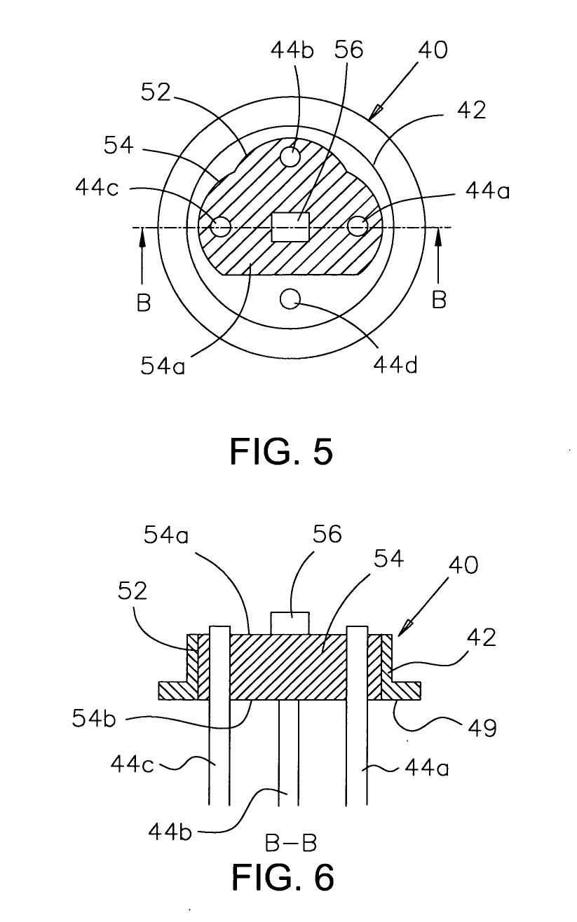

FIGS. 5 and 6 show a large-area insert hole 52 formed on a metal stem 42 of a header 40. More particularly, the area of the insert hole 52 includes the central region of the metal stem 42 and the neighboring peripheral regions. An insulating structure 54 may be located in the insert hole 52, or may be formed in the insert hole 52 by way of injection molding. It is to be noted that pin-leads 44a to 44c are located within the range of the insert hole 52 and have first ends combined with the insulating structure 54. Also, an opto-electronic chip 56 is located on a first end 54a of the insulating structure 54.

The metal stem 42, each of the pin-leads 44a to 44c and the pin-lead (ground electrode) 44d (see FIG. 5) may be combined together, and then the combined assembly is introduced into the proper injection molding machine and mold. Then, the insert molding is performed to inject the insulating material into the insert hole 52 to form the insulating structure 54, which also combines the pin-leads 44a to 44c together. In addition, the ground electrode 44d may be combined with the metal stem 42 according to the mold closing pressure in the injection molding process, or the ground electrode 44d may be additionally pressed to combine with the metal stem 42.

In addition, FIG. 6 shows that a second end 54b of the insulating structure 54 is level with a second surface 49 of the metal stem 42 or a hole periphery of the insert hole 52. However, according to the descriptions mentioned hereinabove, the second end 54b may also be higher or lower than the second surface 49 of the metal stem 42, or the following descriptions of the embodiments may be referred to.

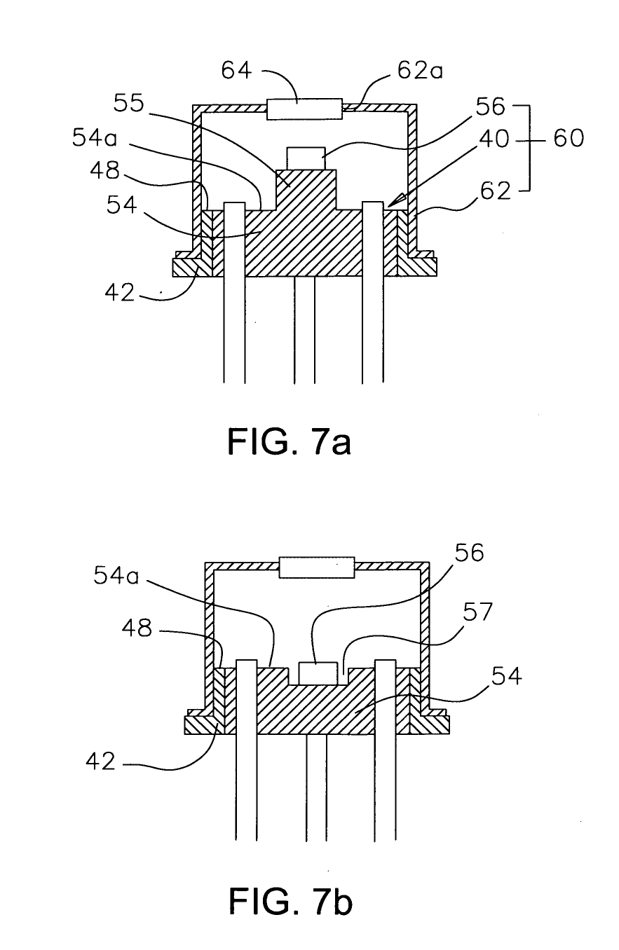

FIG. 7a shows an opto-electronic element 60 including the header 40, the opto-electronic chip 56 and a cap 62. More particularly, the first end 54a of the insulating structure 54 has an integrally formed pedestal 55, which protrudes beyond the first surface 48 of the metal stem 42, wherein the opto-electronic chip 56 is located on the pedestal 55. Thus, the opto-electronic chip 56 is electrically isolated from the metal stem 42, and the relative position between the opto-electronic chip 56 and the optical device 64 on the cap 62 can be adjusted to enhance the light coupling efficiency.

According to the teachings of the above-mentioned embodiment, the optical device 64, such as a lens or a glass piece, is located in an opening 62a. Alternatively, no element or device is located in the opening 62a.

Also, according to the teachings of the embodiment, FIG. 7b shows that the first end 54a of the insulating structure 54 may have a recess 57, which may be lower than the first surface 48 of the metal stem 42, wherein the opto-electronic chip 56 is located in the recess 57.

The insulating structures 24 and 54 may support the opto-electronic chips 26 and 56 using the recess 57 of the first ends 24a and 54a, and the first ends 24a and 54a may be level with, higher than or lower than the first surfaces 18 and 48.

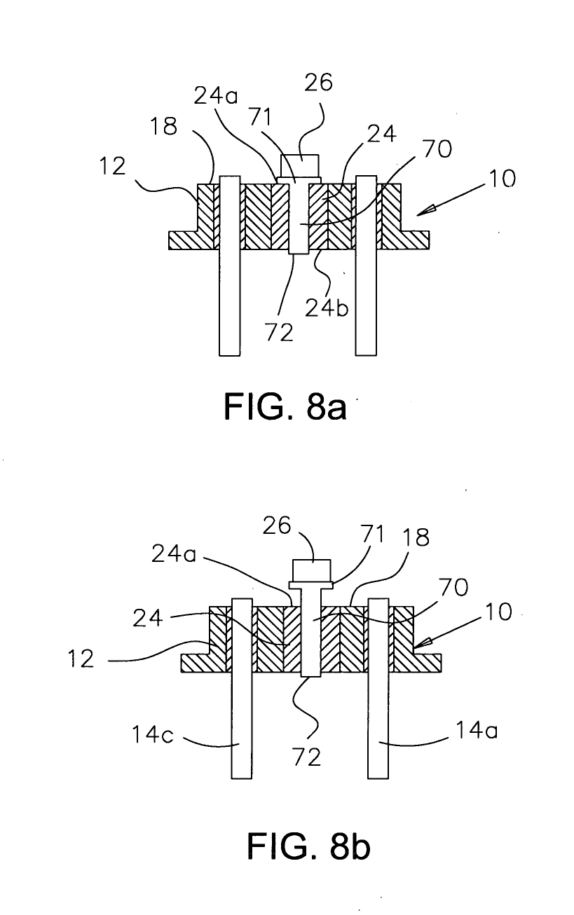

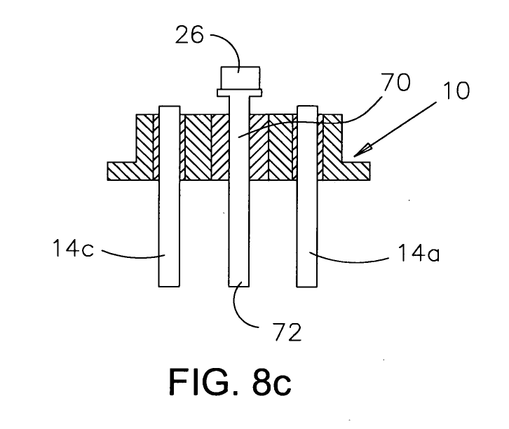

FIG. 8a shows that an auxiliary pin 70 is located in an axial direction of the insulating structure 24. The auxiliary pin 70 has a first position 71 and a second position 72. The first position 71 may be exposed from the first end 24a of the insulating structure 24 and neighbor the first surface 18 of the metal stem 12. The second position 72 may pass through the second end 24b of the insulating structure 24. The opto-electronic chip 26 is located on the first position 71.

FIG. 8b shows that the first position 71 of the auxiliary pin 70 may significantly protrude from the first end 24a of the insulating structure 24 or the first surface 18 of the metal stem 12 so that the height of the opto-electronic chip 26 can be adjusted. In addition, the shape of the first position 71 can be made a tack or jut shape.

Furthermore, in the structures of FIGS. 8a and 8b, the second position 72 of the auxiliary pin 70 and the end portions of the pin-leads 14a and 14c are significantly located at different horizontal positions. For example, a portion of the auxiliary pin 70 may be cut. So, when the header 10 or the opto-electronic element is located on the circuit board, the second position 72 of the auxiliary pin 70 is floating and cannot be connected to the circuit so that the open circuit is formed.

According to the implementation concept that the first ends 24a and 54a of the insulating structures 24 and 54 may be level with, higher than or lower than the first surface 18 of the metal stem 12, the first position 71 of the auxiliary pin 70 may also be designed to be level with, higher than or lower than the first surface 18 of the metal stem 12.

The opto-electronic chip 26 may be the conventional N+ based chip having two electrodes made of different metal layers and located on top and bottom sides. Because the electrode on the bottom side of the opto-electronic chip 26 contacts with the first position 71 of the auxiliary pin 70, the first position 71 may serve as the wire bonding position.

If the two electrodes of the opto-electronic chip 26 are located on the same side, such as the top side, then the open-circuited auxiliary pin 70 cannot affect the electrode property of the element.

FIG. 8c shows another embodiment, in which the length of the auxiliary pin 70 is adjusted or changed so that the second position 72 and the end portions of the other electrodes 14a and 14c are located at the equivalent or the same horizontal position. When the header 10 or the opto-electronic element is located on the circuit board, the auxiliary pin 70 may be electrically connected to the circuit to form the close state. More particularly, the electrodes of the opto-electronic chip 26 are located on the top and bottom sides, and the electrode on the bottom side may be electrically connected to the auxiliary pin 70, and the auxiliary pin 70 may serve as the electrode.

The structure of FIGS. 2 and 3 is selected as the header 10 in FIGS. 8a to 8c, so each of the pin-leads 14a to 14d is isolated from the insulating structure 24. However, the structure of the header 40 in FIGS. 5 and 6 may also be selected, and the auxiliary pin 70 may be located in the axial direction of the insulating structure 54 according to the teachings of the above-mentioned embodiment so that one end of each of the electrodes 44a to 44c is inserted into the insulating structure 54.

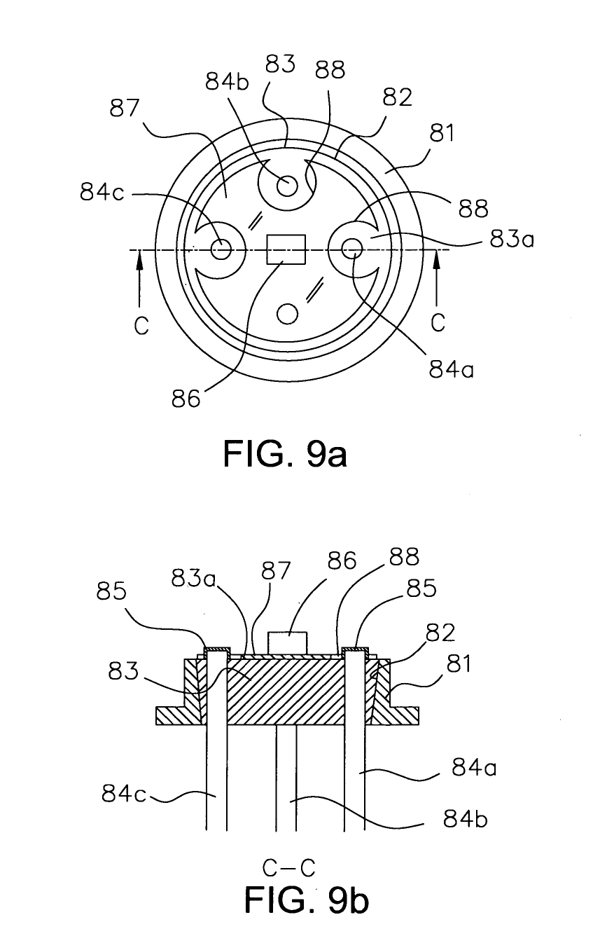

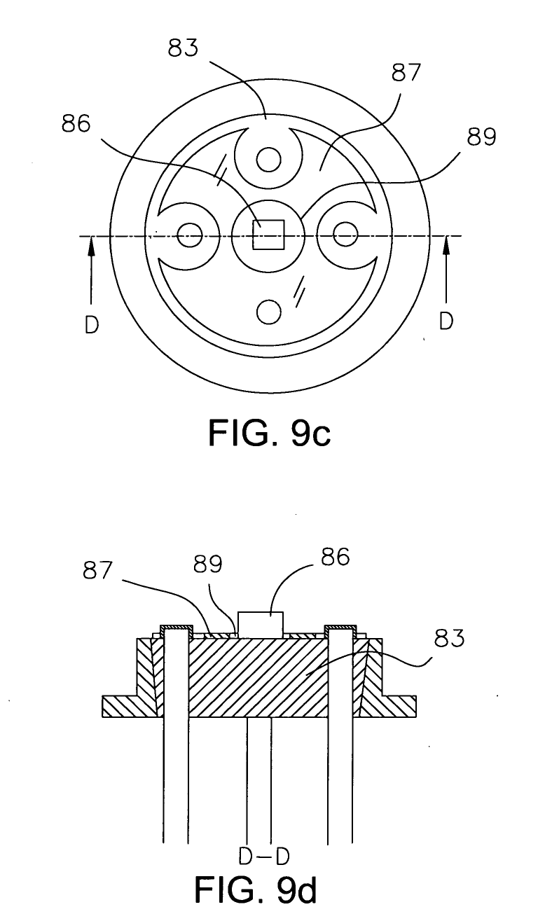

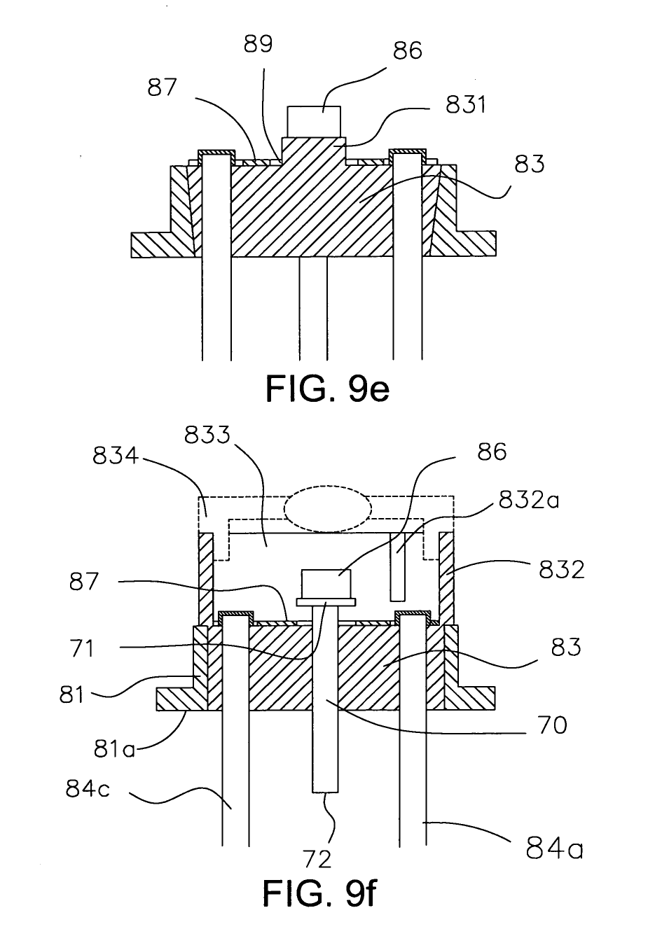

As shown in FIGS. 9a and 9b, an insert hole 82 is formed on a metal stem 81, and an insulating structure 83 is inserted into the insert hole 82. More particularly, each of a plurality of pin-leads 84a to 84c has one end passing through the insulating structure 83, and an end portion of each of the pin-leads 84a to 84c has a good electro-conductor 85 (see FIG. 9b). The good electro-conductor 85 may be made of gold.

In addition, a metal film 87 is located or plated on the surface of a first end 83a of the insulating structure 83 so that the metal film 87 is electrically connected to the metal stem 81. The periphery of the metal film 87 has notches 88 corresponding to the electrodes 84a to 84c, so that each metal film 87 is electrically isolated from the corresponding one of the electrodes 84a to 84c. The opto-electronic chip 86 is located on the metal film 87. If the opto-electronic chip 86 has an electrode located on the bottom surface and in contact with the metal film 87, then the metal film 87 may serve as the wire-bonding region.

As shown in FIG. 9b, the insert hole 82 may be a cone-type hole, and the external shape of the insulating structure 83 is manufactured to conform to the shape of the insert hole 82. Thus, the insulating structure 83 may be tightly inserted into and positioned with the insert hole 82.

The embodiment of FIGS. 9c and 9d differs from that of FIGS. 9a and 9b in that the metal film 87 is formed with an opening 89, and an opto-electronic element 86 is located in the opening 89 and on the insulating structure 83. The metal film 87 may be optionally electrically connected to the metal stem 81.

FIG. 9e shows the modification of the embodiment of FIG. 9d, and is characterized in that a pedestal 831 is protruding formed on the surface of the insulating structure 83 and passes through the opening 89 of the metal film 87, and the opto-electronic chip 86 is located on the end portion of the pedestal 831.

As shown in FIG. 9f, the periphery of the insulating structure 83 may be further extended to form an extended wall portion 832. One end of the extended wall portion 832 is an open end having a slot 833. A cap 834 is located on the open end of the extended wall portion 832 so that the configuration of the opto-electronic element can be formed.

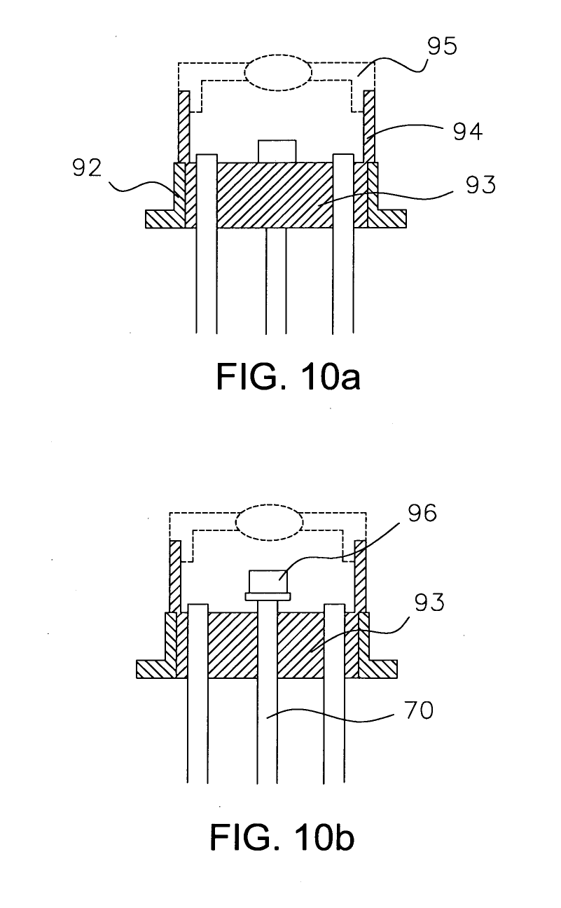

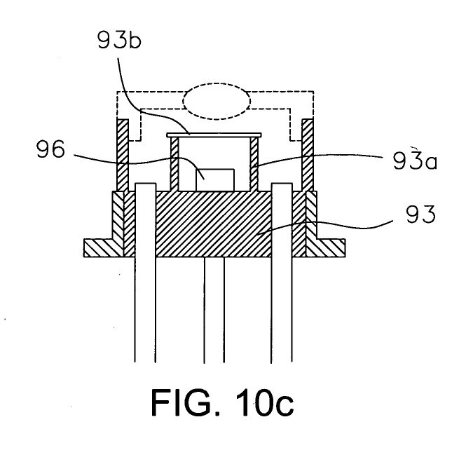

In addition, the extended wall portion 832 has a notch 832a so that the tip bonding head can easily approach the element. Similarly, the notch may also be adopted in the structures of FIGS. 10a, 10b, 12a, 12b and 13a.

Furthermore, the auxiliary pin 70 may be located in the axial direction of the insulating structure 83. The first position 71 thereof may support the opto-electronic chip 86. Adjusting the length or height of the auxiliary pin 70 can adjust the height of the opto-electronic chip 86. Also, if the length of the second position 72 of the auxiliary pin 70 extending out of the insulating structure 83 is such that the second position 72 becomes floating with respect to other pin-leads 84a and 84c (i.e., if the second position 72 of the auxiliary pin 70 is closer to the second surface 81a of the stem 81 than the free ends of the pin-leads 84a and 84c), then the auxiliary pin 70 may form the open circuit without being located on the circuit whenever the opto-electronic element is positioned. If the length or position of the second position 72 extending out of the insulating structure 83 corresponds to the end portion (free end) of the electrodes 84a and 84c, then the auxiliary pin 70 may serve as the electrode connected to the circuit.

In addition, if the auxiliary pin 70 is required to have the sufficient length for the connection to the circuit, and the auxiliary pin 70 and the opto-electronic chip 86 need to form the insulation or open circuit, an insulating layer structure, such as the spin on glass (SOG) may be located under the base of the opto-electronic chip 86 and in contact with the auxiliary pin 70.

The first position 71 of the auxiliary pin 70 of FIG. 9f significantly projects beyond the surface of the metal film 87 or the metal stem 81 so that the object of adjusting the height of the location of the opto-electronic chip 86 may be achieved. In addition, the structure of the extended wall portion 832 of FIG. 9f is also adapted to the header structures of FIGS. 9b and 9d.

As shown in FIG. 10a, an insulating structure 93 having an extended wall portion 94 is inserted into a metal stem 92 in an axial direction, and a cap 95 is combined with the extended wall portion 94. The difference between this embodiment and the embodiment of FIGS. 9a to 9f resides in that no metal film is located on the surface of the insulating structure 93 in this embodiment.

As shown in FIG. 10b, the auxiliary pin 70 is located in the axial direction of the insulating structure 93. The height or position of an opto-electronic chip 96 can be adjusted by adjusting the length and the position of the auxiliary pin 70. Next, according to the descriptions mentioned hereinabove, the auxiliary pin 70 may be equivalent to an electrode of the opto-electronic chip 96 according to the requirement, or the auxiliary pin 70 and the electrode of the opto-electronic chip 96 may be open circuited.

The above-mentioned stems 12, 42 and 81 mainly contain the metal structures combined with the insulating structures 24, 54 and 83 made of the non-metal or insulating material. In addition to the above-mentioned structures, however, other constitution structures may also be adopted.

As shown in FIG. 10c, a projecting supporting structure 93a is formed on the insulating structure 93, and an optical device 93b is located on the supporting structure 93a and located opposite the opto-electronic chip 96. The optical device 93b may be a filter or a monitor photo-diode (MPD), while the supporting structure 93a may be a pair of projecting cylinders, rings or other structures, which are sufficient to support the optical device 93b or provide the mounting position of the optical device 93b.

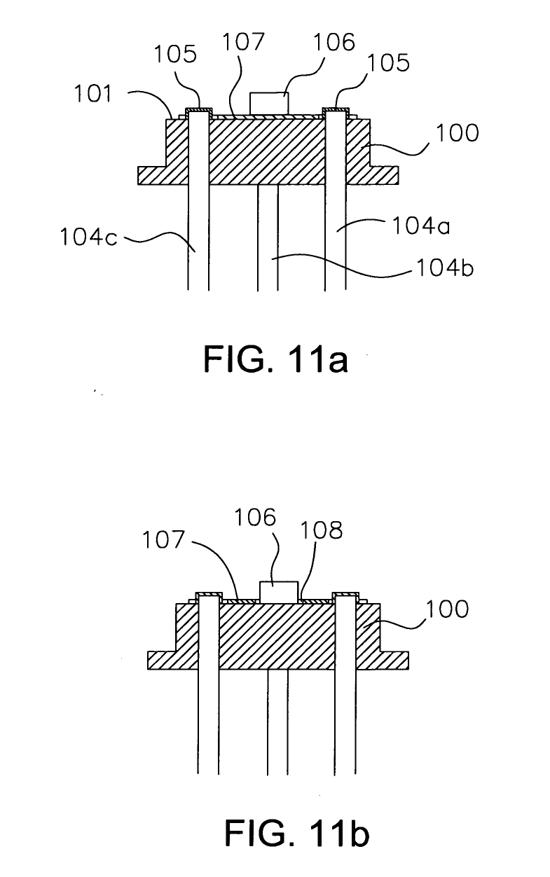

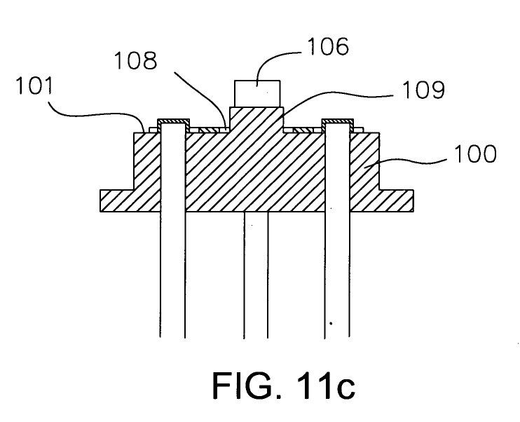

FIG. 11a discloses a non-metal stem 100, wherein a plurality of pin-leads 104a to 104c is located in the axial direction of the non-metal stem 100. One end of each of the pin-leads 104a to 104c may project beyond the first surface 101 of the non-metal stem 100, and a good electro-conductor 105 is located on the surface of each of the pin-leads 104a to 104c. Also, a metal film 107 is located on a surface of the non-metal stem 100, and the opto-electronic chip 106 is located on the metal film 107. Thus, the electrode of the opto-electronic chip 106 can be electrically connected to the pin-lead 104a or 104c via a wire (not shown). Alternatively, the metal film 107 is electrically connected to an electrode of the opto-electronic chip 106, and then a wire (not shown) connects the metal film 107 to the pin-lead 104a or 104c to form the electrical connection.

In FIG. 11a, if the good electro-conductor 105 on the pin-lead 104a, 104b or 104c is connected to the metal film 107, then the pin-lead 104a, 104b or 104c can be electrically connected to the opto-electronic chip 106 without the wire.

The structure of FIG. 11b differs from the structure of FIG. 11a in that the metal film 107 is formed with an opening 108, and the opto-electronic chip 106 is located within the range of the opening 108 and on the surface of the non-metal stem 100.

The structure of FIG. 11c differs from the structure of FIG. 11b in that the non-metal stem 100 has the integrally formed pedestal 109. The pedestal 109 is higher than the first surface 101 and can pass through the opening 108 to support the opto-electronic chip 106. Thus, the pedestal 109 has the function of adjusting the height of the opto-electronic chip 106.

It is to be noted that the pedestal 109 has the insulating property and thus may be equivalent to the insulating structure of the above-mentioned embodiment. It is further derived that the central region of the non-metal stem 100 may be defined as the insulating structure for supporting the opto-electronic chip 106. Also, according to the description of the invention, the insulating structure may be level with, higher than or lower than the first surface 101 of the non-metal stem 100.

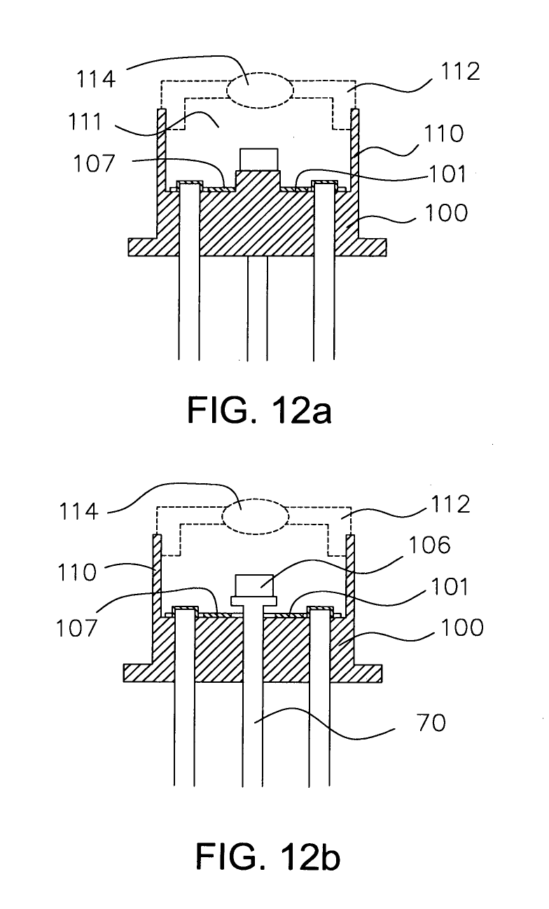

As shown in FIG. 12a, the periphery of the non-metal stem 100 may be extended to form an extended wall portion 110 of a ring structure. On end of the extended wall portion 110 is an open end having a slot 111. A cap 112 is located on the open end of the extended wall portion 110. Next, one end of the cap 112 may have an optical device 114, such as a (spherical) lens, a (plane) glass. Alternatively, one end of the cap 112 is only formed with an opening without any element being located.

As shown in FIG. 12b, an auxiliary pin 70 is mounted in an axial direction of the non-metal stem 100. One end of the auxiliary pin 70 projects beyond the first surface 101 of the non-metal stem 100 and supports the opto-electronic chip 106. The cap 112 is located on the open end of the extended wall portion 110. The auxiliary pin 70 projects beyond the first surface 101 by a length or height for adjusting the height of the location of the opto-electronic chip 106 so that the opto-electronic chip 106 approaches the optical device 114 of the cap 112. In addition, the auxiliary pin 70 may also serve as an electrode of the opto-electronic chip 106, or form the open state.

In the embodiment of FIGS. 12a and 12b, a metal film 107 may be located on the first surface 101 of the non-metal stem 100.

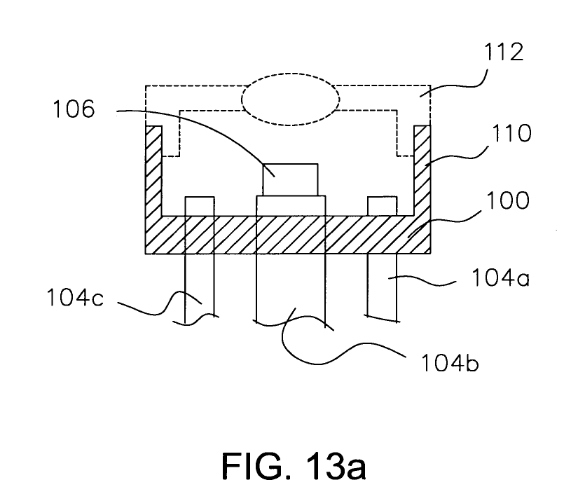

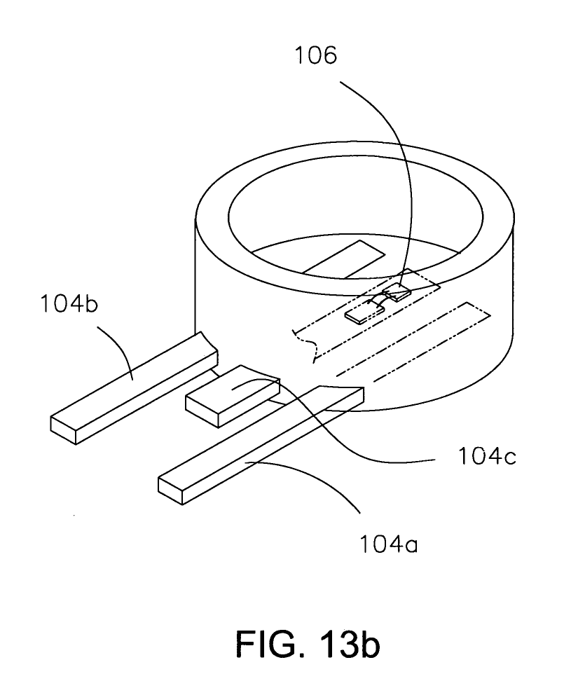

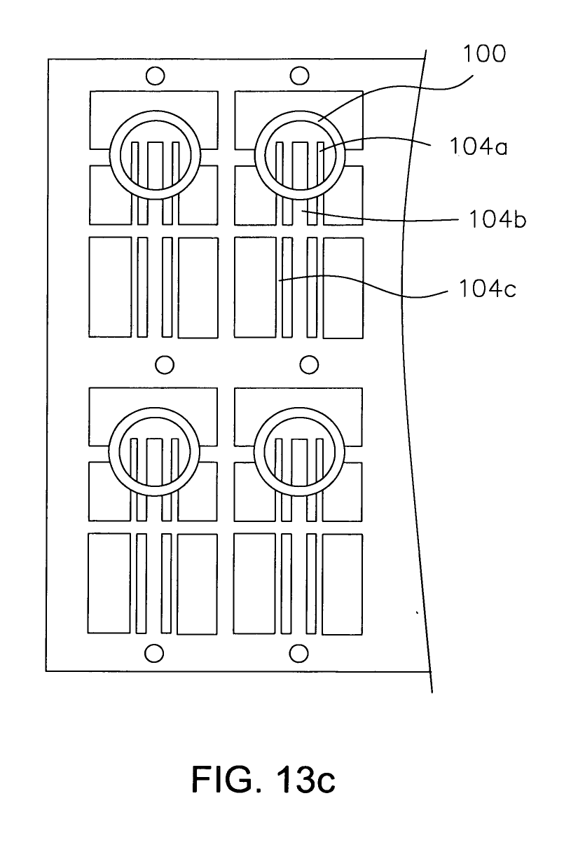

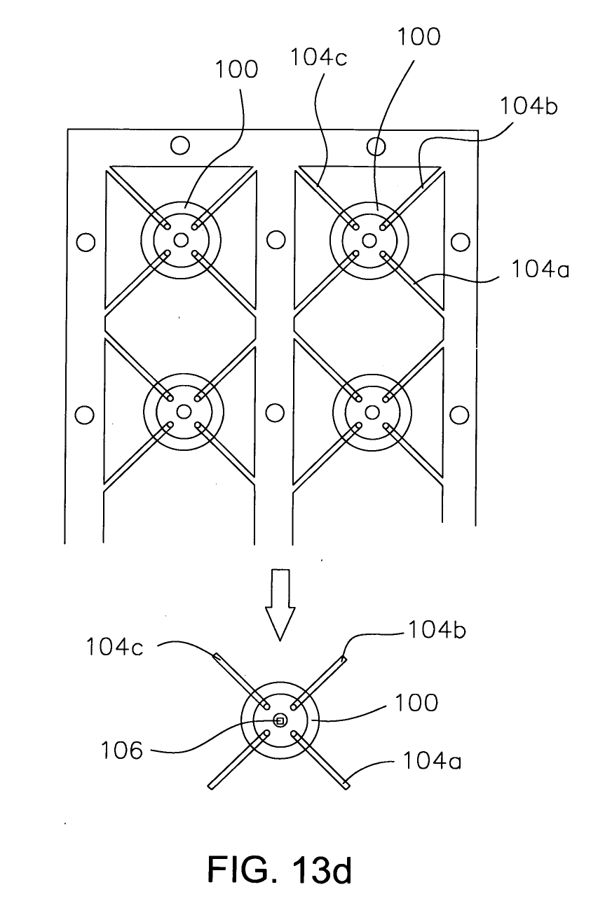

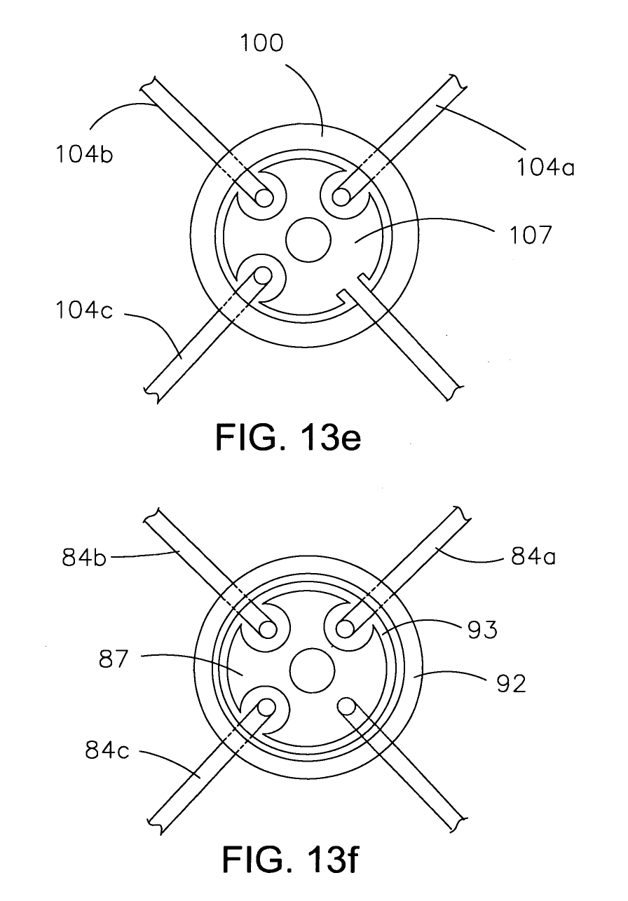

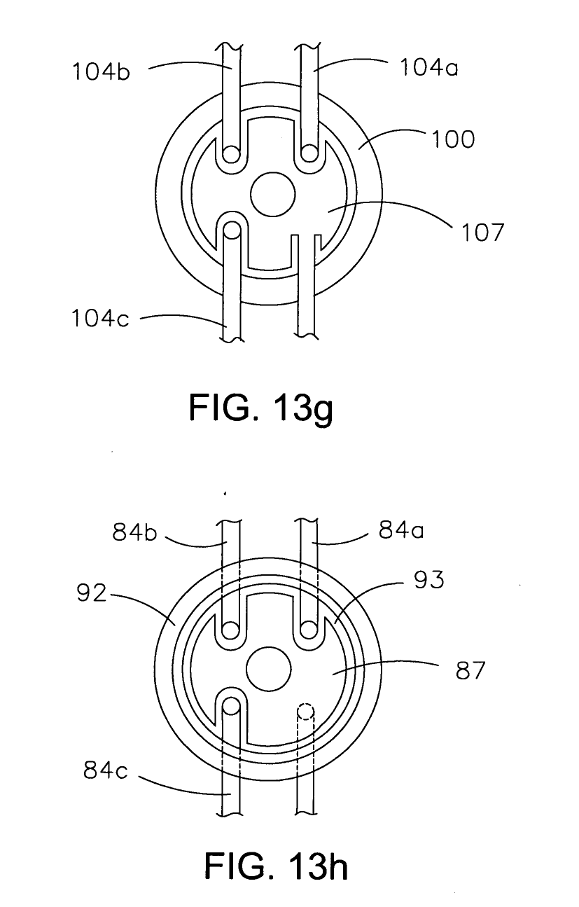

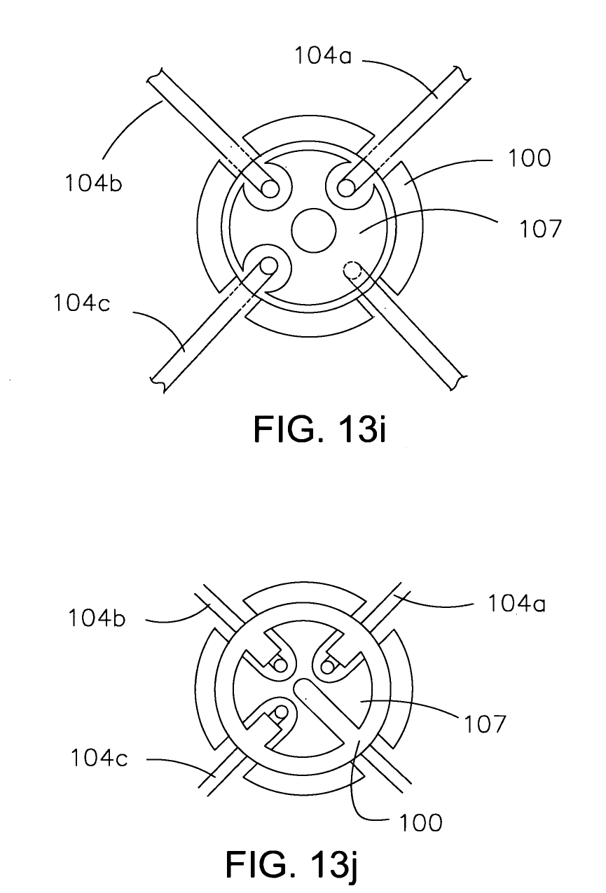

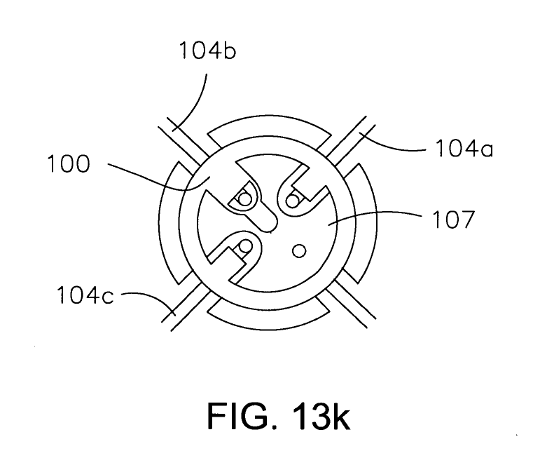

As shown in FIG. 13a, a cap 112 is located on the extended wall portion 110 of the non-metal stem 100, a plurality of pin-leads 104a to 104c is inserted in the axial direction of the non-metal stem 100, the opto-electronic chip 106 or any other opto-electron/electrical element is located on one of the pin-lead 104b, and the pin-lead 104b may form the open circuit or serve as an electrode. The difference between this embodiment and that of FIG. 12b is that no metal film is provided in this embodiment.

The difference between the configurations of FIGS. 13b and 13a resides in the direction in which each of the pin-leads 104a to 104c is inserted into the non-metal stem 100. In addition, the opto-electronic chip 106 is a PIN diode and electrically connected to a transimpedance amplifier (TIA). The pin-lead 104c is in a floating state, so the pin-lead 104c forms the open circuit.

According to the structure pattern shown in FIG. 13b, the header may be manufactured to have the patterns shown in FIGS. 13c and 13d. A continuous metal tape or metal sheet having the proper pin-leads 104a to 104c may be manufactured in advance. Then, a non-metal stem 100 is formed on one end of each of the pin-leads 104a to 104c (see FIG. 13c) or on the gathering portion (see FIG. 13d) by way of injection molding. Thus, the non-metal stem 100 and each of the pin-leads 104a to 104c may be injection molded more conveniently.

Taking FIG. 13d as an example, after the continuous tape-like or sheet-like header structure is formed, the opto-electronic chip 106, matching elements and bonding wires (not shown) may be located on each header. Then, the header structure is cut to form into several independent opto-electronic elements.

Regarding the conventional opto-electronic element, a single header is formed, and then the opto-electronic chip and the bonding wires are located on the small header. It is not easy to position the headers one by one. In this invention, many headers constitute the continuous tape or the large-area sheep so that the manufacturing apparatus can conveniently clamp and position the headers. So, the invention can eliminate the conventional inconvenience caused by the placement of the opto-electronic chip and the wire bonding.

According to the disclosures and the teachings of FIGS. 13b to 13d, the combinations of the non-metal stem 100 and each of the electrodes 104a to 104c may contain the patterns and equivalents of FIGS. 13e, 13g, and 13i to 13k. A metal film 107 may be disposed on the non-metal stem 100.

Also, the electrodes 84a to 84c in FIGS. 13f and 13h are disposed in the horizontal direction of the hybrid architecture composed of the metal stem 92 and the insulating structure 93. A metal film 87, which may be electrically connected to the metal stem 92, is located on the insulating structure 93.

Each of the insulating structures 24, 54, 83 and 93 in the above-mentioned embodiments may form an independent insulating member on the corresponding one of the metal stems 12, 42, 81 and 92, or form an independent insulating member in conjunction with the auxiliary pin 70. Furthermore, the end surfaces of the insulating structures 24, 54, 83 and 93 may be level with, higher than or lower than the surfaces of the metal stems 12, 42, 81 and 92, and the opto-electronic chips 26, 56, 86 and 96 may be located on the independent insulating member.

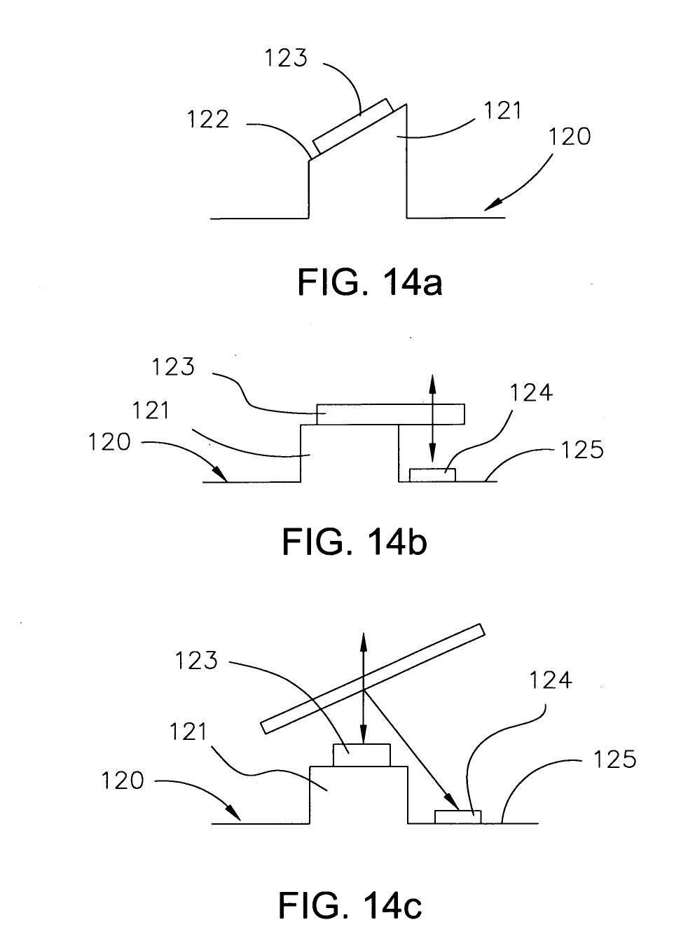

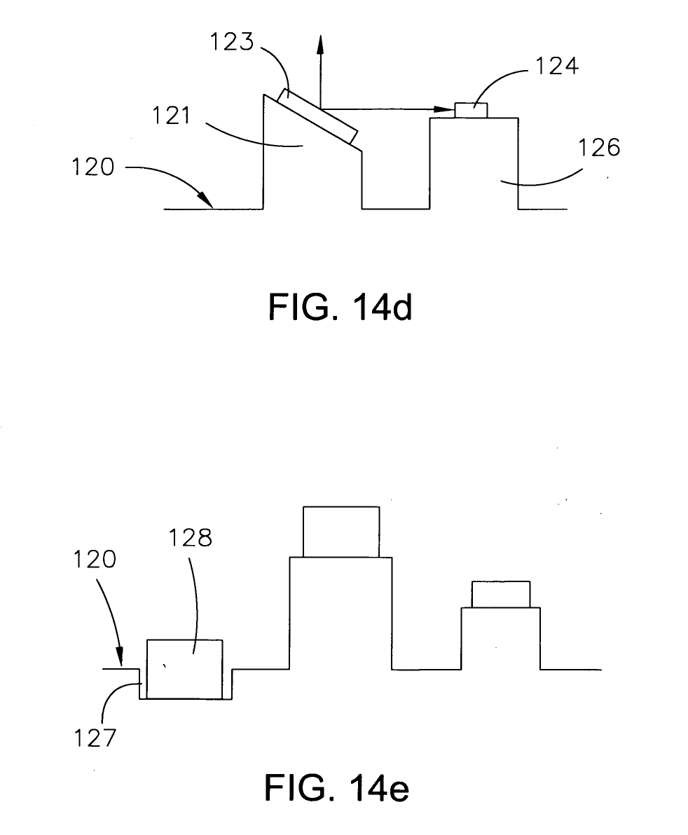

In addition to the above-mentioned architecture, however, FIG. 14a shows that an insulating structure 120 may have a cylinder 121 and an inclined end surface 122. An optical element/device 123 is slantingly located on the end surface 122. Also, FIGS. 14b and 14c show that optical elements/devices 123 and 124 are located on the projecting cylinder 121 and a smooth surface 125 of the insulating structure 120. As shown in FIG. 14d, the insulating structure 120 may have two cylinders 121 and 126, on which the optical elements/devices 123 and 124 are respectively located. As shown in FIG. 14e, the insulating structure 120 may further have a cavity 127, in which the optical element/device 128 may be located.

According to the teachings of FIGS. 14a to 14e, one or many cylinders 121 and 126 and cavities 127 may be formed on the insulating structure 120, and an end surface thereof may be formed with an inclined surface or a horizontal surface. The corresponding optical elements/devices 123, 124 may further be disposed on the cylinders 121 and 126, the cavity 127 and the surface 125 of the insulating structure 120, so that the opto-electronic property required by the opto-electronic element can be satisfied. Any combination using the above-mentioned conditions can be adopted to reduce the return loss, or to satisfy the requirement of the monitor photo-diode for generating the feedback control or monitor.

Taking FIG. 14a as an example, the optical element/device 123 may be a surface-emitting laser VCSEL or a photo-diode (non-MPD). Taking FIG. 14b as an example, the optical element/device 124 may be a surface-emitting laser, and the other optical element/device 123 may be a filter or a MPD. Taking FIG. 14c as an example, the optical element/device 123 may be the VCSEL, and the other optical element/device 124 is the MPD, and the optical element/device located above the optical element/device 123 is the filter. Taking FIG. 14d as an example, the optical element/device 123 is the VCSEL, and the other optical element/device 124 is the MPD.

However, each of the optical element/devices 123, 124 and 128 in FIGS. 14a to 14e may be partially or entirely replaced with an opto-electronic chip.

Next, no matter what the positions and the patterns of the insulating structures 24, 54, 83 and 93 of the invention are, the areas (projection areas) of the insulating structures 24, 54, 83 and 93 displayed on the stems 12, 42, 81 and 92 have to at least correspond to the projection areas of the opto-electronic chips 26, 56, 86 and/or 96 on the stems 12, 42, 81 and 92.

Regarding the insulating structures 24, 54, 83 and 93, the projection areas on the stems 12, 42, 81 and/or 92 may be properly enlarged in addition to the above-mentioned requirements. For example, the projection areas of the insulating structures 24, 54, 83 and/or 93 on the stems 12, 42, 81 and/or 92 may be restricted within the range of the inscribed circle of each electrode pin. Alternatively, the projection areas of the insulating structures 24, 54, 83 and/or 93 on the stems 12, 42, 81 and/or 92 could be up to 56% of the areas contained in (constituted by) the outer peripheries of the stems 12, 42, 81 and/or 92, respectively. In another embodiment, the projection areas of the insulating structures 24, 54, 83 and/or 93 displayed on the stems 12, 42, 81 and 92 are within the range of 10% to 56% of the projection area of the stem surface. In addition, regarding the volume, the volumes of the insulating structures 24, 54, 83 and/or 93 may range between the volumes of the opto-electronic chips 26, 56, 86 and/or 96 and 56% of the volumes of the stems 12, 42, 81 and/or 92, respectively. The volumes of the insulating structures 24, 54, 83 and/or 93 may also be reduced and restricted between 2% and 20% of the volumes of the stems 12, 42, 81 and/or 92, respectively. Moreover, regarding the volume of the opto-electronic chip 26, 56, 86 or 96 serving as the reference, the volumes of the insulating structures 24, 54, 83 and/or 93 range between 2 and 20 times of the volumes of the opto-electronic chips 26, 56, 86 and/or 96, respectively.

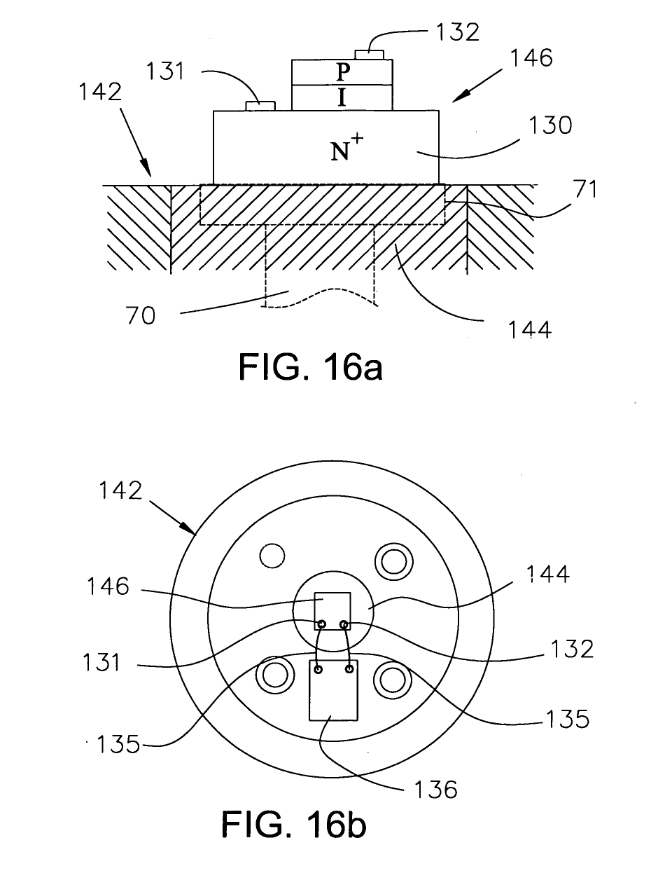

Similarly, the projection area of the insulating structure 144 in the following FIGS. 16a and 16b falls within the above-mentioned restrictive range.

The opto-electronic chip in each embodiment may be the conventional opto-electronic chip located on the header of the invention to constitute the opto-electronic element. However, the following structure of the opto-electronic chip may further be adopted.

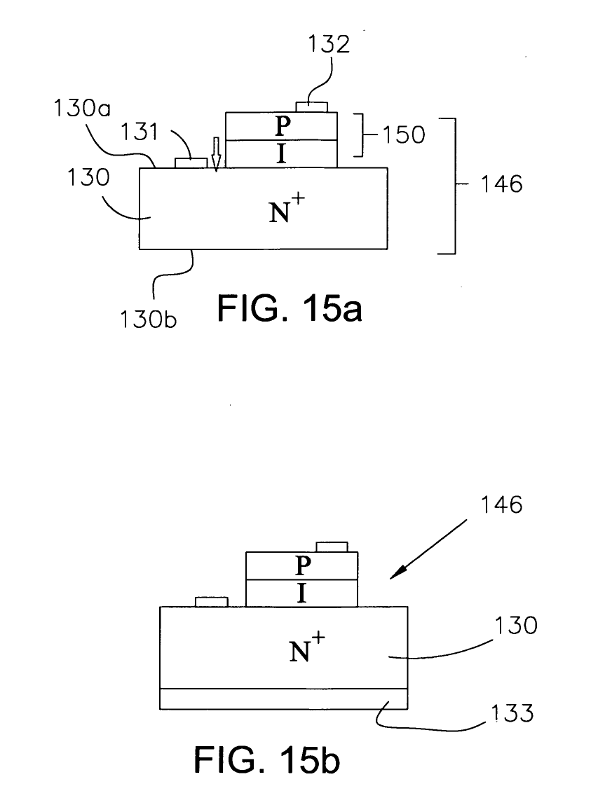

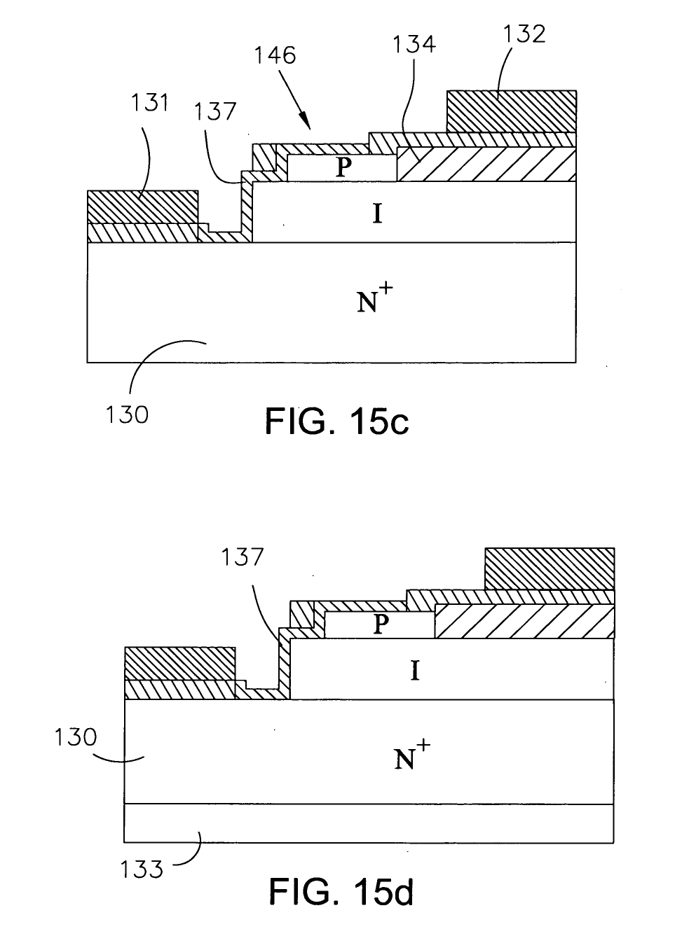

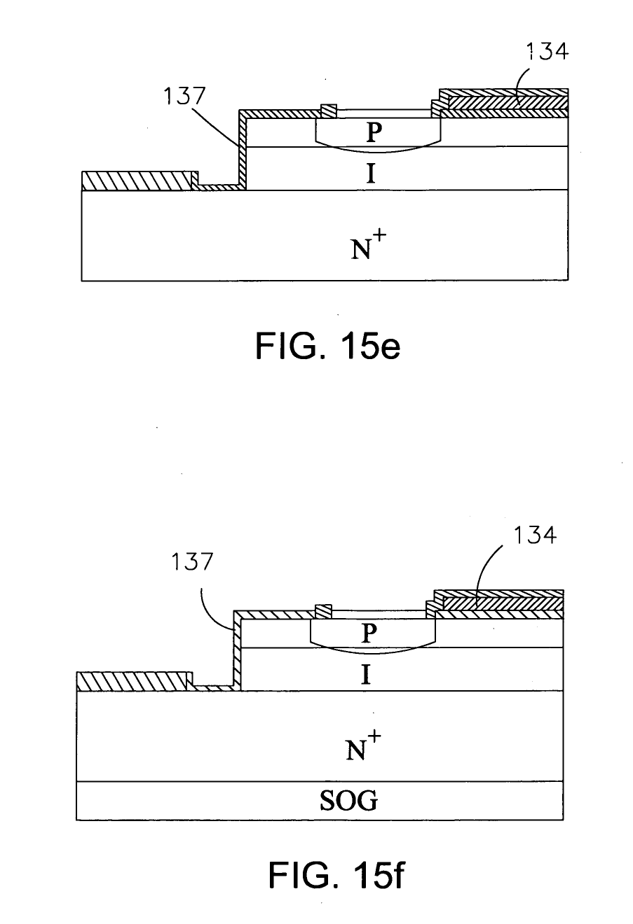

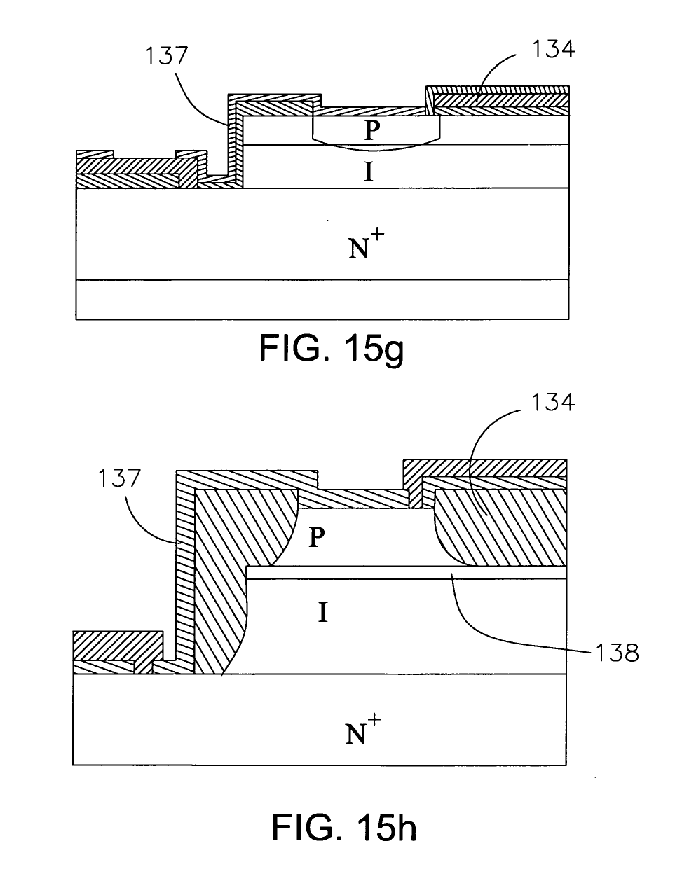

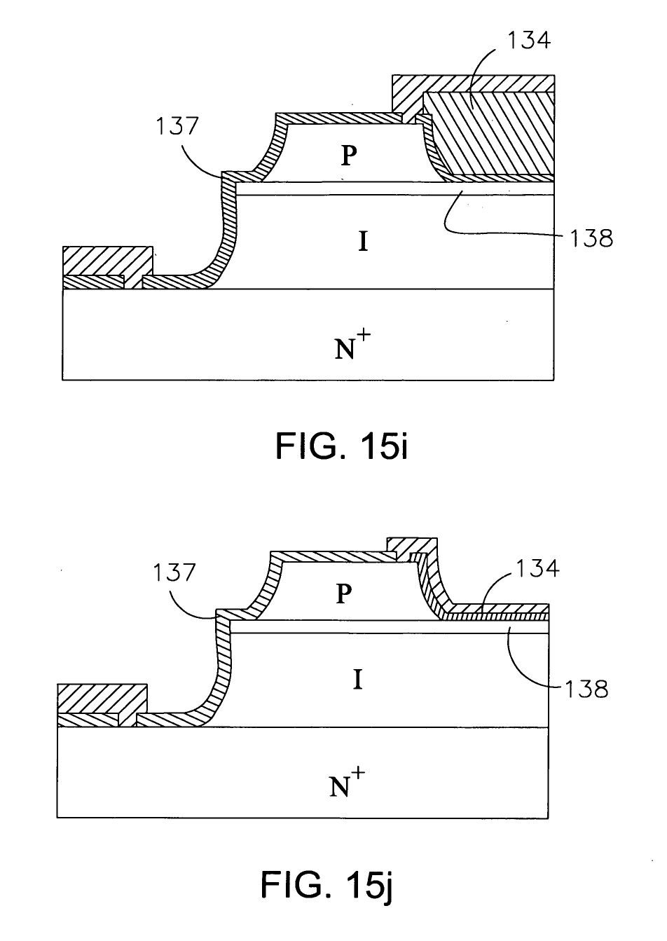

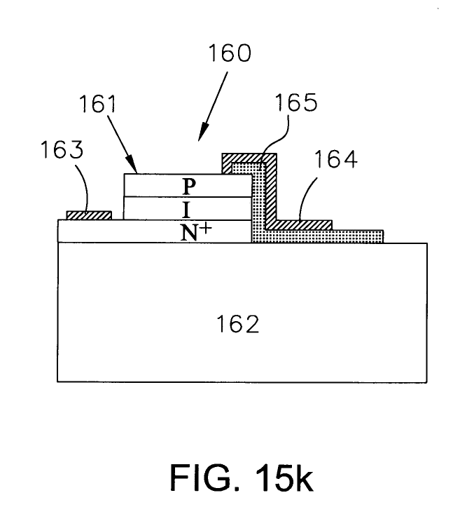

As shown in FIG. 15a, an opto-electronic chip 146, which can replace the opto-electronic chip 26, 56, 86, 96 or 106, includes an epitaxy layer structure 150, which has a second polarity and is formed on a base 130 having a first polarity by way of epitaxy. The first polarity is different from the second polarity. For example, the epitaxy layer structure 150 in the drawing includes a P epitaxy layer, and may further include an I epitaxy layer or any other auxiliary epitaxy layer with another function, wherein the base 130 is a N+ base.

According to the above-mentioned composition, the invention may also adopt the epitaxy layer structure 150 having the N epitaxy layer in conjunction with a P base. No matter which combination is adopted, the thickness of the base 130 has to be much greater than the thickness of the epitaxy layer in the epitaxy layer structure 150.

In the example of FIG. 15a, the P epitaxy layer is used in conjunction with the N base. The base 130 is a highly-doped electroconductive header (N+ base). The epitaxy layer structure 150 having a plurality of epitaxy layer is grown on a first side 130a of the base 130. Next, the electrodes 131 and 132 having the same metal constitution are formed on the side of the epitaxy layer structure 150, such as the top side in the drawing.

Moreover, the highly doped electroconductive base 130 has the greater thickness, ranging between 50 and 1000 um, and usually ranging between 70 and 700 um, so that the firm support may be obtained. So, the thickness of the electroconductive base 130 may range between several tens to several hundreds of times of the thickness of the conventional N epitaxy layer. With the progress of the manufacturing technology, however, the thickness in the future may further be reduced while still satisfying the firm support. When the independent electrode 131 is formed as the bonding pad by etching, the bonding pad still can keep the electrode property even if the portion surface of the electroconductive base 130 is etched. Thus, the structure of the opto-electronic chip 146 of this embodiment still keeps the flexibility of the manufacturing process control. In addition, the second side (bottom surface) 130b of the N-type electroconductive base 130 does not have the semi-insulating or non-electroconductive base with the same material.

In addition, the two electrodes 131 and 132 have the same electroconductive metal structure, which is usually the Schottky metal structure, especially the Ti/Pt/Au stacked metal structure, wherein Ti (having the better adhesive property to the semiconductor) usually ranges from 10 to 100 nm, Pt (a barrier metal, which may be omitted from some embodiments) usually ranges from 50 to 200 nm, and Au (for the subsequent wire bonding or connection) usually ranges from 100 to 2000 nm. However, if the electro-plating process is combined therewith, the thickness of Au may reach several microns. The titanium metal may be replaced with chromium (Cr) so that metal architecture of the electrode 131 or 132 becomes the Cr/Au or Cr/Pt/Au architecture.

In the above-mentioned epitaxy layer, the thickness of the P-type epitaxy layer usually ranges from 100 to 2000 nm, and the thickness of the I-type epitaxy layer usually ranges from 500 to 5000 nm.

The structure of the opto-electronic chip of FIG. 15a may be particularly used in conjunction with the headers used in FIG. 2, 3, 4a, 4b, 5, 6, 7a, 7b, 8a, 8b, 9c, 9d, 9e, 10a, 10b (e.g., when the auxiliary pin is in the open state), 11b, 11c, 12a, 13b, 14a to 14e because each of the headers usually has an insulating structure or has an auxiliary pin located at a level different from that of other pin-leads. So, the opto-electronic chip 146 may be placed on the header without the submount when the low-cost N+ base 130 of the invention is used in conjunction with the P electrode 132 and the N electrode 131 made of the same material. Thus, the cost and the element capacitor can be decreased, and the high-frequency response property can be enhanced.

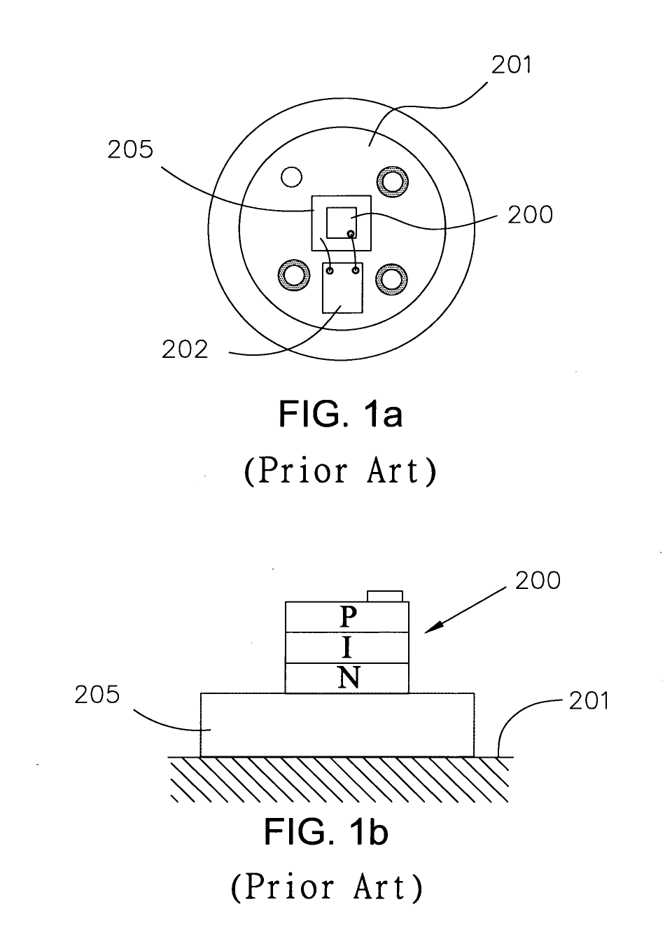

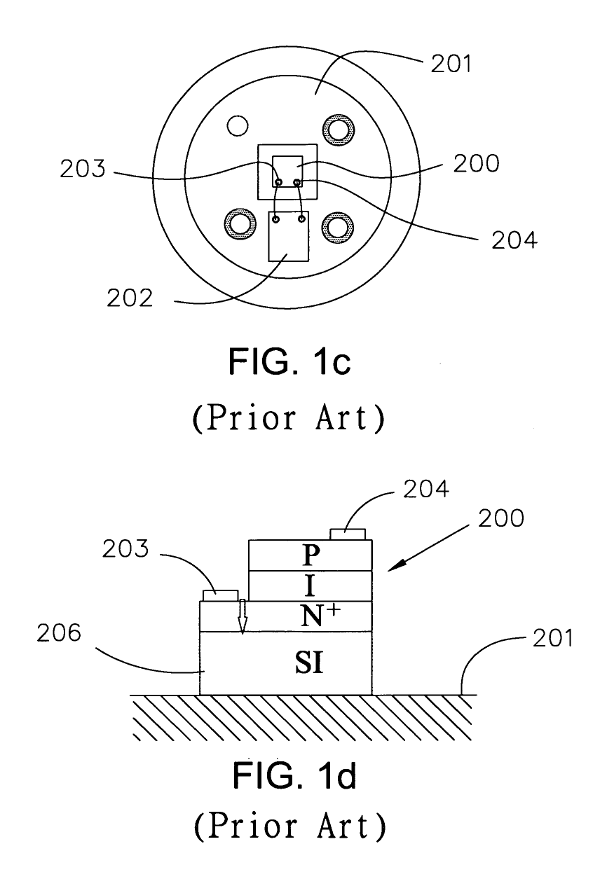

As shown in FIG. 15b, the difference between this embodiment and that of FIG. 15a is that an insulating layer 133, such as spin on glass (SOG) or spin on dielectric (SOD) or a CVD dielectric layer, is disposed on one side of the electroconductive base 130. The pattern of this structure may be adapted to various headers in FIGS. 2 to 14e or to the conventional header in FIG. 1a or 1c. In this case, the heterogeneous substrate (submount 205) may be omitted or reserved.

In FIG. 15c, the PIN architecture is depicted in detail, and a low dielectric constant layer (low-K layer) 134 is located under the P electrode and filled within the region where the P epitaxy layer is etched off. Alternatively, the low-K layer 134 is located between the two electrodes 131 and 132 in order to lower the element capacitance. The low-K layer 134 may be replaced by a thick film.

The opto-electronic chip 146 in FIGS. 15a to 15c is designed according to each header with the insulating structure, and the opto-electronic chip 146 may be used in conjunction with each header to form the opto-electronic element satisfying the novelty and the inventive step.

The difference between FIGS. 15d and 15c resides in that the bottom surface of the electroconductive base 130 has an insulating layer 133. In addition, an insulating protection layer 137 is located in the epitaxy layer structure in each of FIGS. 15c to 15j.

Following the contents of the embodiment of FIGS. 15c and 15d, the opto-electronic chip may have the architecture shown in FIGS. 15e to 15j. FIGS. 15e and 15f disclose a diffusion type PIN architecture, which may have a low-K layer 134 or a thick layer. FIGS. 15g to 15j disclose a mesa type PIN architecture having a low-K layer 134 or a thick layer, wherein the dielectric constant or the thickness of the thick layer is designed according to the standard of reducing the capacitance by more than 20%.

Also, FIGS. 15h to 15j disclose an interface epitaxy layer 138 located between the P epitaxy layer and the I epitaxy layer. The interface epitaxy layer 138 is the undoped or lowly-doped InP or InAlAs layer. This is the high bandgap material for reducing the leakage current, and the high bandgap material usually has the thickness ranging between 10 to 200 nm.

The low-K layer 134 or thick layer may be the SOG coating, the SOD or the CVD dielectric layer.

FIG. 15k shows the structure of an opto-electronic chip 160, which may be used in a photo-diode (PD). The opto-electronic chip 160 includes an epitaxy layer structure 161 grown on a base 162. The epitaxy layer structure 161 includes a P-I-N+ epitaxy layer, and the base 162 is a semi-insulating base or a non-electroconductive base, such as indium phosphide (InP) or gallium arsenide (GaAs) base. Next, two electrodes 163 and 164 (or bonding pads) are disposed on the same side of the epitaxy layer structure 161. In detail, the two electrodes 163 and 164 may be located on different levels, but can be seen when viewed from the top side.

The electrode (bonding pad) 163 is electrically connected to the N+ epitaxy layer, and the other electrode (bonding pad) 164 is electrically connected to the P epitaxy layer. More particularly, the structure of the electrode 164 has the side wall structure. That is, the electrode 164 passes through the lateral side of the epitaxy layer structure 161, and has one end located on the base 162, and the other end electrically connected to the P epitaxy layer with the partial area. Thus, the capacitance between the two electrodes (bonding pads) 163 and 164 may be effectively reduced.

Moreover, an insulating layer 165 may be located between the electrode 164 and the epitaxy layer structure 161 and the base 162. According to the teachings of the embodiment, the two electrodes 163 and 164 may have the same metal architecture.

FIGS. 16a and 16b show the PIN-TIA opto-electronic element architecture, wherein a header 142 has an insulating structure 144 (see the above-mentioned header structure). An opto-electronic chip 146 is disposed on the insulating structure 144, and the electroconductive base 130 is disposed on the surface of the insulating structure 144 so that the opto-electronic chip 146 is insulated from the header 142. In addition, two pin-leads 131 and 132 are electrically connected to a transimpedance amplifier 136 (see FIG. 16b) via wires 135.

According to the teachings of the embodiment, the two electrodes may also be electrically connected to at least one portion of the pin-leads. The electrical connection includes the connection between the electrode and the electrode pin, the connection directly through the wire to the electrode pin, or the connection to the electrode pin indirectly through the wire, the electrode and other active/passive component, transimpedance amplifier, capacitor and the like. The direct or indirect connection between the electrode and the electrode pin still falls within the scope of the electrical connection.

The electroconductive base 130 of the above-mentioned embodiment is a homogeneous base having the cost lower than that of the conventional semi-insulating substrate. In addition, the combination of the electroconductive base 130 and the insulating structure 144 may satisfy the requirement of the insulation between the opto-electronic element 146 and the header 142 without the submount. Thus, the cost can be reduced, and the bandwidth can be increased.

Next, because the electroconductive base 130 is very thick, the electroconductive base 130 cannot be easily etched through when the electrode 131 is formed by way of etching. Thus, the etching control is simple, the manufacturing parameters are flexible, and the yield is high.

As shown in FIG. 16a, an auxiliary pin 70 may further be located in the axial direction of the insulating structure 144. The first end 71 of the auxiliary pin 70 may support the opto-electronic chip 146. When the first end 71 of the auxiliary pin 70 projects beyond the insulating structure 144, the height of the location of the opto-electronic chip 146 may be adjusted.

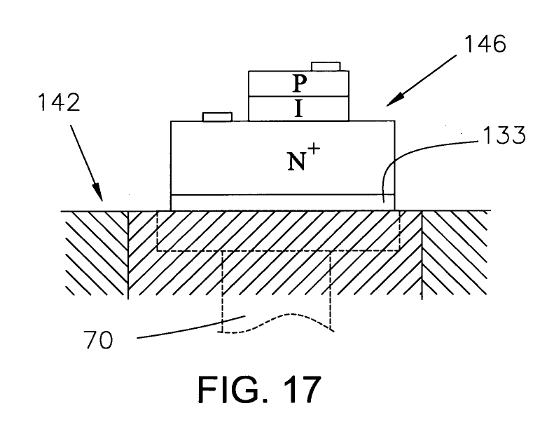

FIG. 17 shows the example of the PIN-TIA architecture. The difference between this embodiment and the previous embodiment resides in that the opto-electronic chip 146 has the insulating layer 133. So, the auxiliary pin 70 and the opto-electronic chip 146 are open circuited through the insulating layer 133. In addition, the opto-electronic chip 146 and the header 142 are also open circuited.

In addition to the doped N-type base, the electroconductive base 130 of the invention may have a doped P-type base in conjunction with the P-type epitaxy layer. At this time, the PIN structures of FIGS. 15a to 15c and 16a and 17 are placed inversely.

Also, according to the teachings of the embodiment, the header may be a metal stem combined with a plurality of pin-leads. An insert element of an insulating structure is inserted into the metal stem. The insulating insert element forms an independent insulating member.

In addition, the header may be composed of a metal stem, an inserted metal stem with an insulating structure, and a plurality of pin-leads. The insulating structure forms an independent insulating member.

Moreover, the header is composed of a non-metal stem and a plurality of pin-leads, and the insulating structure is a portion of the non-metal stem or the entire non-metal stem.

The number of the pin-leads in the embodiment is only for the illustrative purpose only. In practice, the number of the electrodes ranges from 2 to 6, and may also be increased according to the requirements.

Each header of the invention includes a TO-can architecture or a Leadframe architecture, has an insulating structure, and can be used in conjunction with the opto-electronic chip to form the opto-electronic element. The opto-electronic chip may be a conventional architecture, such as a semi-insulating substrate having the P-I-N epitaxy layer. The opto-electronic chip may also be the new chip (the architecture of the embodiment) according to the invention. The structure of the opto-electronic chip includes an electroconductive base (N+ base) on which the P-I-N epitaxy layer is located, and the second side (bottom surface) of the base does not have the same material of semi-insulating or non-electroconductive base. Furthermore, the same metal layer structure serves as the P and N electrodes of the opto-electronic chip. In addition, the second side (bottom surface) of the electroconductive base may also be provided with the SOG or SOD or CVD dielectric material. The chip may be used in conjunction with the low-K (BCB or SOG) material so that the capacitance is further reduced, and the bandwidth may be increased.

The terms of “open circuit” and “insulating” disclosed in this invention mean that, when one end is inputted with a normal voltage or current signal, an output of the signal cannot be easily obtained at the other end. The P-I-N+ structure mentioned in this invention may have an n buffer layer, an undoped or lowly-doped InP or InAlAs layer, which does exist in some embodiments but is omitted from this embodiment. Thus, any P-I-N+ structure having either the buffer layer or other epitaxy layer for optimizing the element property should be regarded as falling within the equivalent scope of the invention.

In addition, the first surface of the insulating structure of the invention may correspond to the first surface of the metal stem to form the projecting, planar or depressed structure. Similarly, the second surface of the insulating structure of the invention corresponds to the second surface of the metal stem to form the projecting, planar or depressed structure, which is still deemed as falling within the equivalent scope of the invention.

In addition, the optimum design of the insulating structure according to the embodiment of the invention is that the insulating structure is located at the geometric center of the metal stem corresponding thereto. The opening formed on the metal film may also be located at the geometric center of the non-metal stem corresponding thereto without any limitative purpose.

Next, the N-type electroconductive substrate is used in conjunction with the P epitaxy layer of the epitaxy layer structure in the opto-electronic chip of the invention. However, the P-type electroconductive substrate may also be used in conjunction with the N epitaxy layer of the epitaxy layer structure in the opto-electronic chip in an equivalent manner. So, the P-type substrate used in conjunction with the N epitaxy layer is still deemed as falling within the equivalent scope of the invention.

Also, a heterogeneous substrate (submount) may also be located between the electroconductive base and the header according to the actual product requirement, so that the position of the opto-electronic chip can be adjusted.

While the invention has been described by way of examples and in terms of preferred embodiments, it is to be understood that the invention is not limited thereto. To the contrary, it is intended to cover its equivalent modifications. Therefore, the scope of the appended claims should be accorded the broadest interpretation so as to encompass all such modifications.

What is claimed is:

1. A header structure of an opto-electronic element for supporting an opto-electronic chip, comprising:
a stem having a first surface on one side of a thickness direction of the stem, and a second surface on the other side of the thickness direction of the stem;
an insulating structure, which has a first end and a second end, is combined with the stem and is for supporting the opto-electronic chip;
a plurality of pin-leads combined with the stem or the insulating structure.

2. The header structure according to claim 1, wherein the stem is made of a metal material and has an insert hole, the insulating structure is an insert element made of an insulating material and located in the insert hole, the first end neighboring the first surface of the stem supports the opto-electronic chip, and the first end may be higher than, lower than or level with the first surface of the stem.

3. The header structure according to claim 1, wherein the first end of the insulating structure has a pedestal, the pedestal protrudes beyond the first surface of the stem and supports the opto-electronic chip.

4. The header structure according to claim 1, wherein the first end of the insulating structure has a cavity, which is lower than the first surface of the stem and for accommodating the opto-electronic chip.

5. The header structure according to claim 1, further comprising an extended wall portion, which extends from the insulating structure, projects beyond the stem and forms a ring structure, wherein the extended wall portion has an internal space and an end portion, which is an open end having a slot.

6. The header structure according to claim 5, wherein the extended wall portion has a notch.

7. The header structure according to claim 5, further comprising a cap, which has an optical device and is located on the open end of the extended wall portion.

8. A header structure of an opto-electronic element, comprising:
a stem having a first surface on one side of a thickness direction of the stem, and a second surface on the other side of the thickness direction of the stem;
an insulating structure, which is combined with the stem and has a first end and a second end;
a plurality of pin-leads combined with the stem or the insulating structure; and
an auxiliary pin having an end portion respectively defining a first position and a second position and combined with the insulating structure, wherein the first position protrudes beyond the first end of the insulating structure.

9. The header structure according to claim 8, wherein adjusting or changing a length of the auxiliary pin can make the second position be closer to the second surface of the stem than a free end of each of the pin-leads.

10. A header structure of an opto-electronic element for supporting an opto-electronic chip, comprising:
a stem having a stem surface;
an insulating structure, which is combined with the stem and for supporting the opto-electronic chip; and
a plurality of pin-leads combined with the stem or the insulating structure,
wherein a projection area of the insulating structure displayed on the stem is greater than or equal to a projection area of the opto-electronic chip on the stem surface of the stem, and is smaller than 56% of an area defined by an outer periphery of the stem.

11. The header structure according to claim 10, wherein the projection area of the insulating structure on the stem surface of the stem falls within a range of an inscribed circle of each of the pin-leads.

12. The header structure according to claim 10, wherein the insulating structure is partially or entirely higher than, lower than or level with the stem surface of the stem.

13. A header structure of an opto-electronic element for supporting an opto-electronic chip, comprising:
a stem having a stem surface;
an insulating structure, which is combined with the stem and for supporting the opto-electronic chip; and
a plurality of pin-leads combined with the stem or the insulating structure,
wherein a projection area of the insulating structure located on the stem ranges between a projection area of the opto-electronic chip on the stem surface of the stem and a range of an inscribed circle of each of the pin-leads.

14. A header structure of an opto-electronic element for supporting an opto-electronic chip, comprising:
a stem having a stem surface;
an insulating structure combined with the stem; and
a plurality of pin-leads combined with the stem or the insulating structure;
wherein a volume of the insulating structure ranges between a volume of the opto-electronic chip and 56% of a volume of the stem.

15. An opto-electronic element, comprising:
a header combined with an opto-electronic chip, wherein:
the opto-electronic chip comprises:
an electroconductive base having a first polarity, and a first side and a second side in a thickness direction of the electroconductive base;
an epitaxy layer structure located on the first side of the electroconductive base and having a second polarity different from the first polarity; and
two electrodes located on the same side and respectively electrically connected to the epitaxy layer structure and the electroconductive base, wherein the two electrodes have the same electroconductive metal structure; and
the header comprises:
a stem having a first surface and a second surface opposite the first surface;
an insulating structure having a first end and a second end, wherein at least one portion of the insulating structure is located between the first surface and the second surface of the stem; and
a plurality of pin-leads, which is combined with the stem or the insulating structure and is insulated from the insulating structure,
wherein the opto-electronic chip locates in/on the insulating structure of the header, the electroconductive base contacts with the insulating structure, and the opto-electronic chip is electrically connected to at least a portion of the pin-leads via the two electrodes.

16. The opto-electronic element according to claim 15, wherein the second polarity is different from the first polarity means that the electroconductive base of the opto-electronic chip has a highly-doped N-type substrate, and that the epitaxy layer structure comprises a P epitaxy layer.

17. The opto-electronic element according to claim 15, further comprising an auxiliary pin having an end portion, which defines a first position and a second position and is combined with the insulating structure, wherein the first position may be higher than, lower than or level with the first surface of the insulating structure, and the first position is for supporting the opto-electronic chip.

18. The opto-electronic element according to claim 15, wherein the electroconductive base is an N-type base having a thickness ranging from 70 to 700 microns (um).

19. The opto-electronic element according to claim 15, wherein the two electrodes of the opto-electronic chip have the same electroconductive metal structure, which comprises a stacked structure of titanium/gold (Ti/Au) or chromium/gold (Cr/Au).

20. The opto-electronic element according to claim 15, wherein:
the stem is made of a metal material and has an insert hole;
the insulating structure is an insert element made of an insulating material and located in the insert hole;
the first surface of the first end neighboring the stem supports the opto-electronic chip; and
the first end may be higher than, lower than or level with the first surface of the stem.
